(19) United States
(12) Patent Application Publication
(10) Pub. No.: US 2026/0349053 A1
(43) Pub. Date: Nov. 5, 2026

(54) SYSTEMS, METHODS, AND MEDIA FOR ERROR COMPENSATION OF EDDY CURRENT POSITION SENSOR BASED ON INTERNET OF THINGS (IOT)

(71) Applicant: CHENGDU QINCHUAN IOT TECHNOLOGY CO., LTD., Chengdu (CN)

(72) Inventors: Zehua SHAO, Chengdu (CN); Yong LI, Chengdu (CN); Jun WANG, Chengdu (CN); Chang SU, Chengdu (CN); Zilin CHEN, Chengdu (CN)

(73) Assignee: CHENGDU QINCHUAN IOT TECHNOLOGY CO., LTD., Chengdu (CN)

(21) Appl. No.: 19/707,410

(22) Filed: Jun. 15, 2026

(30) Foreign Application Priority Data
May 15, 2026 (CN) 202610676881.1

(51) Int. Cl. G01R 33/00; B23Q 17/10; B23Q 17/12; G01H 13/00; G05B 19/402

(52) U.S. Cl. CPC G01R 33/0082; B23Q 17/10; B23Q 17/12; G01H 13/00; G05B 19/402

(57) ABSTRACT

Disclosed are a system, a method, and a medium for error compensation of an eddy current position sensor based on IoT. The system comprises a management platform and a perception and control platform. The method is executed by the management platform and comprises: determining a spindle offset based on recent spindle speed data, recent eddy current data, and recent temperature data at a preset position; determining a tool elongation based on current spindle speed data and tool machining parameters; determining compensation parameters based on the spindle offset and the tool elongation; generating a plurality of first compensation instructions corresponding to a plurality of compensation moments; at each compensation moment, sending each first compensation instruction to a controller; and controlling, by the controller, a servo motor to rotate by a first angle based on the first compensation instruction to drive a worktable to move by a first compensation amount.

### CROSS-REFERENCE TO RELATED APPLICATIONS

This application claims priority to Chinese Application No. 202610676881.1, filed on May 15, 2026, the entire contents of which are incorporated herein by reference.

### TECHNICAL FIELD

The present disclosure relates to the technical field of IoT numerical control, and particularly relates to a system, a method, and a medium for error compensation of an eddy current position sensor based on Internet of Things (IoT).

### BACKGROUND

With the development of high-end manufacturing, higher requirements are put forward for the machining accuracy of a CNC machine tool. In a precision machining process, errors caused by thermal drift of a spindle, thermal elongation of a tool, and dynamic characteristics of the machine tool are key factors affecting geometric accuracy and surface quality of a workpiece. In order to monitor and compensate for errors in real time, a non-contact eddy current position sensor is widely used in displacement measurement of a machine tool spindle system.

Currently, machine tool error compensation mostly uses a modeling compensation approach based on temperature or simple displacement feedback, making it difficult to effectively eliminate the interference of environmental noise on sensor accuracy and unable to resolve issues such as machine tool structural resonance caused by high-frequency compensation and thermal error lag induced by sudden changes in cutting load, which results in compensation lag and inability to adapt to complex and variable working conditions.

Therefore, it is desirable to provide a system, a method, and a medium for error compensation of an eddy current position sensor based on an IoT, which can overcome the above-mentioned defects and achieve high-precision real-time error compensation that balances anti-noise, vibration suppression, and load adaptation.

### SUMMARY

One or more embodiments of the present disclosure provide a system for error compensation of an eddy current position sensor based on Internet of Things (IoT). The system comprises a management platform and a perception and control platform. The management platform is configured to execute a method for error compensation of an eddy current position sensor based on Internet of Things (IoT).

One or more embodiments of the present disclosure provide a method for error compensation of an eddy current position sensor based on Internet of Things (IoT). The method comprises: determining a spindle offset based on recent spindle speed data of a spindle, recent eddy current data, and recent temperature data at a preset position; determining a tool elongation based on current spindle speed data of the spindle and tool machining parameters; determining compensation parameters based on the spindle offset and the tool elongation, wherein the compensation parameters include a plurality of compensation moments and a plurality of first compensation amounts corresponding to the plurality of compensation moments; generating a plurality of first compensation instructions corresponding to the plurality of compensation moments based on the compensation parameters, wherein each of the plurality of first compensation instructions includes a first angle; and sending, at each of the plurality of compensation moments, a corresponding one of the plurality of first compensation instructions to a controller of a perception and control platform, so that the controller controls, based on the first compensation instruction, a servo motor to rotate the first angle to drive a worktable to move by the first compensation amount.

One or more embodiments of the present disclosure further provide a non-transitory computer-readable storage medium storing computer instructions. When the computer instructions are read by a computer, the computer executes the method for error compensation of the eddy current position sensor based on the IoT.

### BRIEF DESCRIPTION OF THE DRAWINGS

The present disclosure will be further described by way of exemplary embodiments, which will be described in detail by means of the accompanying drawings. These embodiments are not limiting, and in these embodiments, the same numbering denotes the same structure, wherein:

FIG. 1 is a schematic diagram illustrating a platform structure of a system for error compensation of an eddy current position sensor based on an IoT according to some embodiments of the present disclosure;

FIG. 2 is a flowchart illustrating an exemplary method for error compensation of an eddy current position sensor based on an IoT according to some embodiments of the present disclosure;

FIG. 3 is a flowchart illustrating an exemplary process for generating and sending second compensation instructions according to some embodiments of the present disclosure;

FIG. 4 is a schematic diagram illustrating an exemplary process of determining a spindle offset according to some embodiments of the present disclosure; and

FIG. 5 is a flowchart illustrating an exemplary process of generating and sending a third compensation instruction according to some embodiments of the present disclosure.

### DETAILED DESCRIPTION

To more clearly illustrate the technical solutions of the embodiments of the present disclosure, the accompanying drawings to be used in the description of the embodiments will be briefly introduced below. Unless clearly indicated by the context or otherwise specified, like reference numerals in the drawings represent the same structures or operations.

It should be understood that “system”, “device”, “unit”, and/or “module” as used herein are a manner for distinguishing different components, elements, parts, portions, or assemblies at different levels.

Unless the context clearly indicates an exception, the terms such as “a”, “an”, and/or “the” are not intended to specifically refer to the singular, but may also include the plural.

Flowcharts are used in the present disclosure to illustrate operations performed by the system according to embodiments of the present disclosure. It should be understood that the preceding or succeeding operations are not necessarily performed in an exact order. Instead, the various steps may be processed in reverse order or simultaneously.

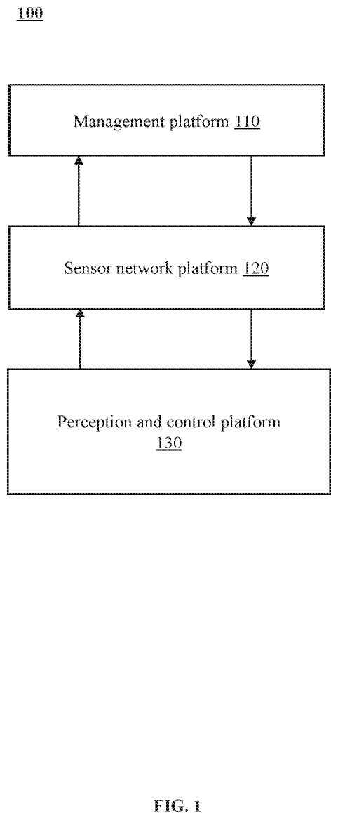

FIG. 1 is a schematic diagram illustrating a platform structure of a system for error compensation of an eddy current position sensor based on an IoT according to some embodiments of the present disclosure. As shown in FIG. 1, a system 100 for error compensation of an eddy current position sensor based on an IoT may include a management platform 110, a sensor network platform 120, and a perception and control platform 130.

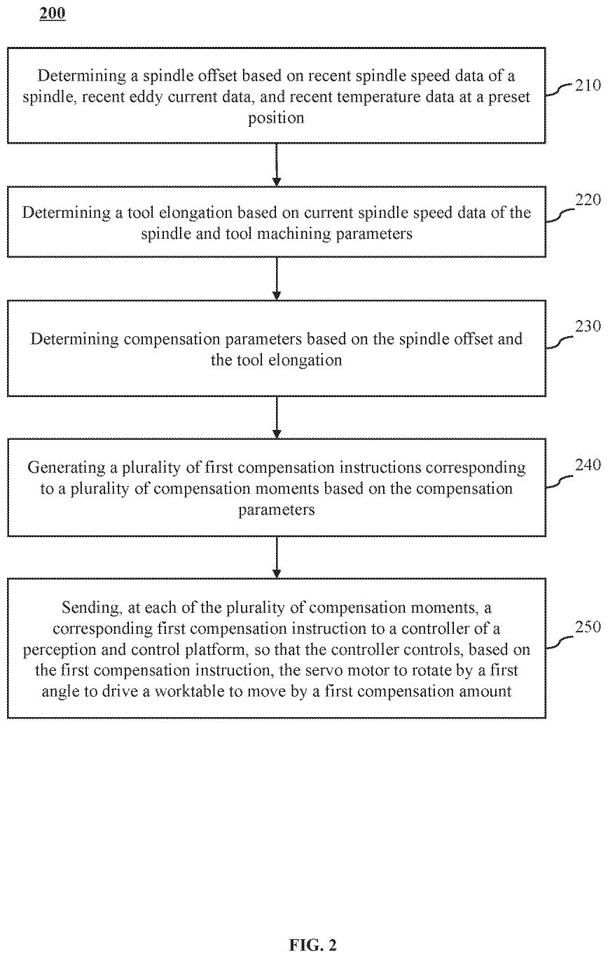

The management platform 110 refers to an integrated platform that coordinates and facilitates connections and collaborations among various functional platforms of the system, and that generates and executes instructions by analyzing and processing data. In some embodiments, the management platform 110 is configured on one or a plurality of servers, where the servers include a memory and a processor. In some embodiments, the management platform 110 may be configured to execute a method for error compensation of an eddy current position sensor based on an IoT. More descriptions regarding the method for error compensation of the eddy current position sensor based on the IoT may be found elsewhere in the present disclosure (e.g., FIGS. 2-5 and the related descriptions thereof).

The sensor network platform 120 refers to an integrated management platform for sensing information, and may be configured as a communication device and/or a gateway, or the like. The sensor network platform 120 may interact with the perception and control platform 130 and the management platform 110, respectively. For example, the sensor network platform 120 is responsible for uploading sensor data collected by sensors of the perception and control platform 130 to the management platform 110, and sending compensation instructions generated by the management platform 110 to the perception and control platform 130.

The perception and control platform 130 refers to a functional platform configured to perform real-time monitoring and intelligent regulation of a machining process of a machine tool. In some embodiments, the perception and control platform 130 may include a numerical control machine tool and components thereof (e.g., a spindle, a worktable, a servo motor, or the like), a controller, and various sensors. In some embodiments, the perception and control platform 130 may embed an Artificial Intelligence (AI) agent. The perception and control platform 130 may be configured to upload various perception information (e.g., data collected by various sensors) to the management platform 110, and accept control from the management platform 110. The perception and control platform 130 may be further configured to perform autonomous analysis and control for specific machining scenarios under a pre-authorization mechanism of the management platform 110. For example, when cutting resistance of the machine tool suddenly increases during machining, the perception and control platform 130 autonomously analyzes and determines a current working condition, and automatically reduces a feeding speed within a pre-authorized range (e.g., limiting an adjustment amplitude of the feeding speed).

The controller may be one or a plurality of types, such as a Computer Numerical Control (CNC) controller, a Programmable Logic Controller (PLC), or the like, and various sensors may include, but are not limited to, an eddy current position sensor configured to collect eddy current data, a speed sensor configured to collect speed data, and a temperature sensor configured to collect temperature data, or the like. The controller is configured to receive the compensation instructions to control the servo motor to rotate, thereby driving the worktable to move. More descriptions regarding this process may be found elsewhere in the present disclosure (e.g., FIGS. 2-5 and the related descriptions thereof).

In some embodiments of the present disclosure, through collaborative work of various platforms of the system for error compensation of the eddy current position sensor based on the IoT 100, a closed-loop control circuit of “perception-transmission-decision-execution” is constructed: the perception and control platform 130 collects multi-dimensional data in real time, which is transmitted via the sensor network platform 120 to the management platform 110 for deep processing and instruction generation, and finally fed back to the perception and control platform 130 for rapid error correction. This architecture not only utilizes powerful computing capabilities of cloud/edge terminals, but also ensures the real-time performance and accuracy of underlying execution.

FIG. 2 is a flowchart illustrating an exemplary method for error compensation of an eddy current position sensor based on an IoT according to some embodiments of the present disclosure. As shown in FIG. 2, a process 200 includes operations 210 to 250. In some embodiments, the process 200 may be executed by the management platform 110 of the system 100 for error compensation of the eddy current position sensor based on the IoT.

In 210, determining a spindle offset based on recent spindle speed data of a spindle, recent eddy current data, and recent temperature data at a preset position.

The spindle refers to a core component of the machine tool configured to drive a tool or a workpiece to rotate. The tool is configured to process the workpiece. The workpiece is a product to be processed, such as a gear shaft, a precision mold core, or the like.

The spindle is affected by a plurality of factors, and its actual position may have an offset relative to a theoretical position. Factors causing the spindle offset include geometric factors (e.g., inherent deviations during manufacturing and assembly), force factors (e.g., offsets caused by loads such as cutting force, centrifugal force, or the like), and thermal factors (e.g., thermal deformation caused by heat generation during operation). Among these, the offset caused by thermal factors most needs to be compensated. In the present disclosure, an offset of the spindle position relative to a cold-state reference position caused by thermal deformation of the spindle is mainly considered, and compensation is performed for the offset. The cold-state reference position refers to a position of the spindle determined in an unoperated and fully cooled state, and is manually pre-measured and recorded.

The machine tool refers to equipment configured to perform cutting and processing on the workpiece. For example, the machine tool may be a high-precision vertical machining center or a five-axis linkage CNC machine tool, or the like. Because a mechanical structure of the machine tool is not a rigid body, when the servo motor quickly performs compensation, the mechanical structure may generate slight vibration, thereby causing quality problems on a surface of the workpiece.

The tool is provided on a front end of the spindle. During high-speed cutting, the tool not only bears a mechanical cutting force but also generates a large amount of cutting heat due to fierce friction with the workpiece, causing thermal elongation of the tool. The tool may include an end mill, a ball-end mill, or a drill, or the like. Tools of different materials and different specifications have different thermal expansion characteristics.

The recent spindle speed data refers to data formed by speeds of the spindle at a plurality of recent moments within a recent period. The recent period may be a period before a current moment (e.g., 1 s or 3 s before the current moment, or the like). The recent period takes the current moment as an end moment. The recent period and the plurality of recent moments within the recent period may be manually preset or set by system default.

In some embodiments, the recent spindle speed data may be collected by a speed sensor provided on the spindle within the recent period, and stored in a memory. The speed sensor may be a photoelectric encoder, a Hall sensor, or the like.

The recent eddy current data refers to data formed by eddy current sensing data of the spindle at the plurality of recent moments within the recent period.

The eddy current sensing data refers to an analog electrical signal (e.g., voltage or current, or the like) monitored and obtained by the eddy current position sensor, which is configured to reflect changes in the spindle position. In some embodiments, the management platform 110 may directly convert the eddy current sensing data into a displacement based on a sensitivity of the eddy current position sensor. The sensitivity is a factory parameter of the eddy current position sensor and may be obtained in advance. For example, the eddy current position sensor with the sensitivity of 8.0 V/mm outputs the eddy current sensing data of 8 V, which represents that the spindle moves by 1 mm.

In some embodiments, the eddy current sensing data may be monitored and obtained by a plurality of eddy current position sensors that are orthogonally arranged. For example, an eddy current position sensor provided on a nose end of the spindle and directly facing an end face of the spindle is configured to obtain the eddy current sensing data reflecting an axial displacement of the spindle; and two eddy current position sensors provided on the nose end of the spindle and directly facing a cylindrical surface of the spindle at a 90° angle are configured to obtain the eddy current sensing data reflecting a radial runout of the spindle.

The axial direction refers to a direction along a centerline of the spindle. In some embodiments, in order to ensure the uniqueness and stability of a measurement datum, the centerline of the spindle may be a theoretical rotational axis of the spindle at the cold-state reference position.

The axial displacement refers to a displacement of the spindle (typically referring to the nose end of the spindle) in the axial direction relative to the cold-state reference position during actual operation (e.g., elongation or shortening).

The radial direction refers to any direction perpendicular to the centerline of the spindle. The radial runout refers to a runout of a rotational center point of the spindle in a radial plane during rotation of the spindle, that is, an offset of the rotational center point during actual rotation of the spindle in the radial plane relative to a theoretical rotational center point. The radial plane is a plane perpendicular to the centerline of the spindle. The theoretical rotational center point is a projection point of the centerline of the spindle on the radial plane. The radial runout may be represented by runout components of the rotational center point of the spindle in two mutually perpendicular directions within the radial plane.

In some embodiments, the axial direction may be denoted as a Z-axis, and the radial direction may include an X-axis and a Y-axis that are mutually perpendicular. An X-Y plane is the radial plane, and the radial plane is perpendicular to the axial direction. Correspondingly, the axial displacement may be denoted as a Z-axis displacement, and the radial runout may include an X-axis runout and a Y-axis runout.

The eddy current position sensor may be an inductive eddy current displacement sensor, a high-frequency reflective eddy current sensor, or the like.

The preset position refers to an arrangement position of a temperature sensor. For example, the preset position may include a front bearing pedestal of the spindle, a rear bearing pedestal of the spindle, a machine tool body, a coolant tank, a surface of a spindle motor, or the like. In some embodiments, the preset position may be preset by a technician based on thermal characteristics of the machine tool.

The recent temperature data refers to temperature values recorded at the preset position within a past period. For example, the recent temperature data may include a temperature change curve at a front bearing within the past 30 minutes. In some embodiments, the recent temperature data is collected and obtained by the temperature sensor at the preset position.

The temperature sensor may be a thermistor, a thermocouple, or an infrared temperature sensor, or the like.

The spindle offset refers to a deviation amount of an actual position of the spindle at a current moment relative to the cold-state reference position. In some embodiments, the spindle offset includes the aforementioned axial displacement (that is, the Z-axis displacement) and the radial runout (including the X-axis runout and the Y-axis runout).

In some embodiments, the management platform 110 may determine the spindle offset by a plurality of ways based on the recent spindle speed data of the spindle, the recent eddy current data, and the recent temperature data at the preset position.

For example, the management platform 110 may construct a first object to be clustered. The first object to be clustered includes a plurality of first clustering vectors corresponding to a plurality of historical periods and a first target vector corresponding to the recent period. The first object to be clustered is subjected to clustering processing to obtain a plurality of first clustering clusters. A first clustering cluster including the first target vector is labeled as a first target cluster, and a mean value of labels corresponding to all first clustering vectors in the first target cluster is statistically determined. The mean value is used as the spindle offset. The historical period is before the recent period.

The first clustering vector is constructed based on historical speed data, historical eddy current data, and historical temperature data within the historical period. A label of the first clustering vector refers to an actual spindle offset obtained by measurement using a high-precision instrument (e.g., a laser rangefinder, or the like) or by calibration after the end of the historical period corresponding to the first clustering vector. The first target vector is constructed based on the recent spindle speed data, the recent eddy current data, and the recent temperature data within the recent period.

A manner of clustering processing includes, but is not limited to, clustering algorithms such as K-means Clustering Algorithm (K-means), Density-Based Spatial Clustering of Applications with Noise (DBSCAN), or the like.

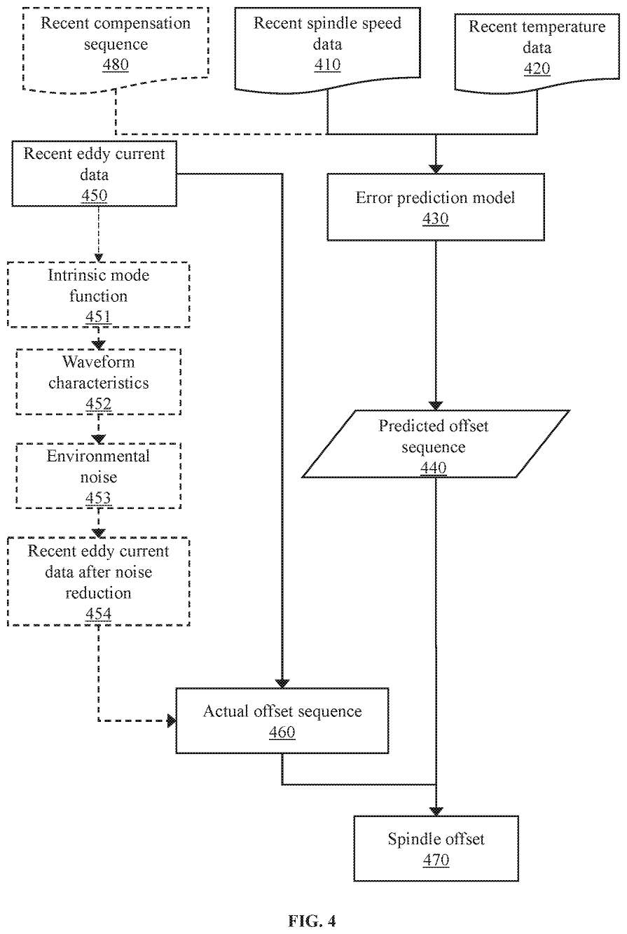

In some embodiments, the management platform 110 may further determine a predicted offset sequence of the spindle based on the recent spindle speed data of the spindle and the recent temperature data at the preset position using an error prediction model; determine an actual offset sequence of the spindle based on the recent eddy current data; and determine the spindle offset based on the predicted offset sequence and the actual offset sequence. More descriptions regarding this portion may be found elsewhere in the present disclosure (e.g., FIG. 4 and related descriptions thereof).

In 220, determining a tool elongation based on current spindle speed data of the spindle and tool machining parameters.

The current spindle speed data refers to a spindle speed at the current moment. The manner of obtaining the current spindle speed data is similar to that of the recent spindle speed data, and thus will not be described in detail herein.

The tool machining parameters refer to working parameters of the tool for machining the workpiece. In some embodiments, the tool machining parameters may include a machining length of the tool (e.g., an overhang length of the tool), tool material data (e.g., a material type and a material thermal expansion coefficient, or the like), and a cutting durating (i.e., a continuous machining duration).

In some embodiments, the tool machining parameters may be obtained by the management platform 110 through parsing a numerical control program (e.g., a G-code), and/or pre-input by a human.

The tool elongation refers to an increment of an axial length of the tool relative to a cold state reference length at the current moment. The cold state reference length refers to an axial reference length of the tool in a non-operating state, which is pre-measured and recorded by a human.

In some embodiments, the management platform 110 may obtain the tool elongation in a plurality of ways based on the tool machining parameters.

For example, the management platform 110 may construct a second object to be clustered. The second object to be clustered includes a plurality of second clustering vectors corresponding to a plurality of historical periods and a second target vector corresponding to the recent period. The management platform 110 may perform clustering processing on the second object to be clustered to obtain a plurality of second clustering clusters; mark a second clustering cluster including the second target vector as a second target cluster; and count a mean value of labels corresponding to all second clustering vectors in the second target cluster, and use the mean value as the tool elongation.

The second clustering vectors are constructed based on historical speed data and historical tool machining parameters within the historical periods. The labels of the second clustering vectors refer to actual elongations of the tool measured by a precision measuring instrument (e.g., a tool setter or a laser measuring instrument) after the historical periods corresponding to the second clustering vectors end; and the second target vector is constructed based on current spindle speed data and current tool machining parameters.

In 230, determining compensation parameters based on the spindle offset and the tool elongation.

The spindle offset needs to be subjected to offset compensation according to a total first compensation amount. The total first compensation amount refers to a total correction amount for performing offset compensation in one direction. The X-axis, the Y-axis, and the Z-axis each have the respective total first compensation amount. The total first compensation amount includes an axial compensation amount (i.e., a Z-axis compensation amount) and a radial compensation amount (i.e., an X-axis compensation amount and a Y-axis compensation amount).

The X-axis compensation amount and the Y-axis compensation amount are configured to compensate for the radial runout of the spindle (including the X-axis runout and the Y-axis runout); and the Z-axis compensation amount is configured to compensate for the axial displacement of the spindle (i.e., the Z-axis displacement) and the tool elongation.

In some embodiments, the total first compensation amount may be decomposed into a plurality of first compensation amounts, so as to perform offset compensation for multiple times.

The compensation parameters refer to relevant parameters configured to perform offset compensation for the spindle offset. In some embodiments, the compensation parameters may include a plurality of compensation moments and a plurality of first compensation amounts corresponding to the plurality of compensation moments.

The compensation moment refers to a future moment for performing an offset compensation action.

The first compensation amount refers to a correction component for performing offset compensation, such as a displacement amount of the worktable at the compensation moment.

In some embodiments, the compensation moment has the corresponding first compensation amount, and each first compensation amount includes an axial compensation component (i.e., a Z-axis compensation component) and a radial compensation component (i.e., an X-axis compensation component and a Y-axis compensation component). A sum of the plurality of first compensation amounts corresponding to the plurality of compensation moments is the total first compensation amount. For example, the X-axis compensation amount is a sum of a plurality of X-axis compensation components corresponding to the plurality of compensation moments, and the Y-axis compensation amount and the Z-axis compensation amount are determined in the same manner.

In some embodiments, the management platform 110 may determine the total first compensation amount based on the spindle offset and the tool elongation; and determine the plurality of compensation moments and the plurality of first compensation amounts corresponding to the plurality of compensation moments based on the total first compensation amount.

For example, the management platform 110 may determine the total first compensation amount for the X-axis, the Y-axis, and the Z-axis by the following formula (1):

Pₜₒₜₐₗ_{ₓ}=−ΔX, Pₜₒₜₐₗ_{_{y}}=−ΔY, Pₜₒₜₐₗ_{_{z}}=−(ΔZ+Lₜₒₒₗ) (1)

where ΔX is the X-axis runout, ΔY is the Y-axis runout; ΔZ is the Z-axis displacement; Lₜₒₒₗ is the tool elongation; Pₜₒₜₐₗ_{ₓ}, Pₜₒₜₐₗ_{_{y}}, and Pₜₒₜₐₗ_{_{z}} are the X-axis compensation amount, the Y-axis compensation amount, and the Z-axis compensation amount, respectively; and the symbol “-” indicates that a compensation direction is opposite to an offset direction.

After obtaining the total first compensation amount, the management platform 110 may determine the plurality of compensation moments and the first compensation amount corresponding to each compensation moment based on the total first compensation amount by means of average distribution. Merely by way of example, the management platform 110 may take N time nodes at equal intervals within a future period as N compensation moments; and for each direction (the X-axis direction, the Y-axis direction, and the Z-axis direction), divide the total first compensation amount of the direction into N portions, thereby obtaining the first compensation amount corresponding to each compensation moment. The future period is a subsequent time period of the current moment. The future period may be preset by a human. For example, the future period may be 10 s after the current moment. In some embodiments, the future period includes the plurality of compensation moments.

That is, for any compensation moment tᵢ, the corresponding first compensation amount ΔPᵢ is expressed by the following formula (2):

$$Δ {P}_{i} = ( \frac{{P}_{{totat}_{x}}}{N} , \frac{{P}_{{total}_{y}}}{N} , \frac{{P}_{{total}_{z}}}{N} ) . \qquad ( 2 )$$

By means of average distribution in a time domain, the larger radial runout or the axial displacement can be decomposed into a series of minute runout increments or displacement increments, thereby facilitating smooth progressive compensation and avoiding machine tool vibration or machining marks caused by an excessively large one-time compensation amplitude.

In 240, generating a plurality of first compensation instructions corresponding to a plurality of compensation moments based on the compensation parameters.

The first compensation instruction refers to a control command configured to drive underlying hardware to perform an offset compensation action. In some embodiments, the first compensation instruction may be in a standard instruction format of a numerical control system (e.g., G-code form) or a pulse instruction format of an underlying driver.

In some embodiments, each compensation moment corresponds to the first compensation instruction, and the first compensation instruction includes a first angle.

The first angle refers to an angle value that the servo motor needs to rotate to achieve the first compensation amount. In some embodiments, the management platform 110 may determine the first angle based on the first compensation amount by querying a first preset table. The first preset table may be manually set based on machine tool specifications and experience. The first compensation amount is positively correlated with the first angle.

In some embodiments, the management platform 110 may determine the first angle corresponding to the servo motor (including first angles corresponding to an X-axis servo motor, a Y-axis servo motor, and a Z-axis servo motor) based on the first compensation amounts corresponding to the compensation moments (including X-axis compensation amounts, Y-axis compensation amounts, and Z-axis compensation amounts). The management platform 110 packages the calculated first angle, a corresponding target axis identifier (e.g., X-axis, Y-axis, Z-axis), and a timestamp (compensation moment) into a data packet, thereby generating the first compensation instructions.

In 250, sending, at each of the plurality of compensation moments, a corresponding first compensation instruction to a controller of a perception and control platform, so that the controller controls, based on the first compensation instruction, a servo motor to rotate by a first angle to drive a worktable to move by a first compensation amount.

In some embodiments, the management platform 110 may send the corresponding first compensation instruction to the controller of the perception and control platform 130 via the sensor network platform 120 at the compensation moment. The controller controls, based on the first compensation instruction, the servo motor to rotate the first angle, thereby driving the worktable to move by the first compensation amount. More descriptions regarding the controller may be found elsewhere in the present disclosure (e.g., FIG. 1 and the related descriptions thereof).

The worktable refers to a component of the machine tool configured to clamp workpieces and drive the workpieces to perform a feeding movement relative to the tool. The worktable may be provided on a linear guide rail, and rotation of the servo motor may drive the worktable to move.

According to some embodiments of the present disclosure, the spindle offset is precisely determined by deeply integrating multi-dimensional data. Concurrently, the compensation parameters, including the plurality of compensation moments and the corresponding first compensation amounts, are comprehensively generated by combining the tool elongation determined based on the current spindle speed data and the tool machining parameters. Ultimately, by issuing the first compensation instruction to the controller, the servo motor is driven to perform a precise rotation action, thereby driving the worktable to move to counteract the aforementioned physical deviation. This ensures the real-time performance and effectiveness of the error compensation, and effectively addresses the problem that traditional machine tool controllers have limited computing power and difficulty running complex thermal error models.

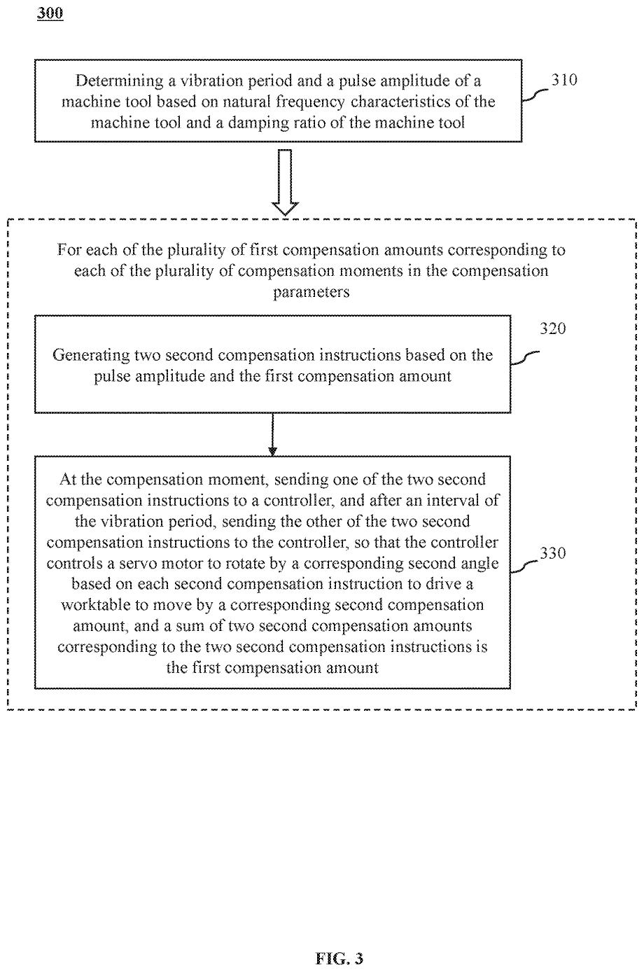

FIG. 3 is a flowchart illustrating an exemplary process for generating and sending second compensation instructions according to some embodiments of the present disclosure. A process 300 includes operations 310 to 330. In some embodiments, the process 300 may be executed by the management platform 110 of the system 100 for error compensation of the eddy current position sensor based on the IoT.

In 310, determining a vibration period and a pulse amplitude of a machine tool based on natural frequency characteristics of the machine tool and a damping ratio of the machine tool.

The natural frequency characteristics refer to free vibration frequencies that are inherent to the machine tool and do not depend on external driving. In some embodiments, the natural frequency characteristics may be manually predetermined.

The damping ratio refers to a dimensionless physical quantity that describes a rate of vibration attenuation of the machine tool structure. In some embodiments, the management platform 110 may determine the damping ratio based on a historical vibration attenuation curve of the machine tool stored in historical data using a logarithmic decrement method.

The vibration period refers to a time required for the machine tool to complete a single damped free vibration. Two second compensation instructions corresponding to a first compensation amount are sent after an interval of the vibration period. In some embodiments, the management platform 110 may determine the vibration period based on the natural frequency characteristics and the damping ratio through the following formula (3):

$${T}_{d} = \frac{1}{2} \times \frac{1}{{f}_{n} \sqrt{1 - {ζ}^{2}}} , \qquad ( 3 )$$

where T_{d} represents the vibration period (unit: s), fₙ represents the natural frequency characteristics of the machine tool (unit: Hz), and ζ represents the damping ratio of the machine tool (dimensionless).

The pulse amplitude refers to a decomposition parameter configured to decompose a single compensation action into multiple actions. By decomposing the compensation action into a plurality of actions using the pulse amplitude, the induced mechanical vibrations are exactly opposite in phase and cancel each other out, allowing the resonance of the mechanical structure to be avoided and the stability of the machine tool to be significantly improved.

In some embodiments, the pulse amplitude may include two sub-amplitudes, which means that a single compensation action is decomposed into two actions. For example, the first compensation amount is decomposed into two second compensation amounts, and the two sub-amplitudes are respectively configured to represent a proportion of the two second compensation amounts. A sub-amplitude may be represented by a numerical value in a range of 0 to 1, and a sum of the two sub-amplitudes corresponding to the two second compensation amounts is 1. More descriptions regarding the second compensation amount may be found in the following related descriptions.

In some embodiments, the management platform 110 may determine the pulse amplitude based on the damping ratio through the following formula (4):

$$K = {e}^{- \frac{ζ π}{\sqrt{1 - {ζ}^{2}}}} , {A}_{1} = \frac{1}{K + 1} , {A}_{2} = \frac{K}{K + 1} , \qquad ( 4 )$$

where K represents a vibration attenuation coefficient (dimensionless); π is a mathematical constant pi; and A₁ and A₂ are respectively the two sub-amplitudes corresponding to the two second compensation amounts, satisfying A₁+A₂=1.

For each first compensation amount corresponding to each compensation moment in the compensation parameters, the management platform 110 may further execute operations 320 and 330.

In 320, generating two second compensation instructions based on the pulse amplitude and the first compensation amount.

More descriptions regarding the first compensation amount may be found elsewhere in the present disclosure (e.g., FIG. 2 and the related descriptions thereof).

In some embodiments, the first compensation instruction corresponds to the generation of two second compensation instructions, and a sum of the two second compensation amounts corresponding to the two second compensation instructions is the first compensation amount corresponding to the first compensation instruction. Correspondingly, since a linear relationship exists between the rotation angle of the servo motor and the displacement of the worktable, a sum of the two second angles included in the two second compensation instructions is the first angle corresponding to the first compensation instruction. That is, the second compensation instruction refers to a sub-instruction generated by decomposing the first compensation instruction to avoid mechanical oscillation caused by single large-magnitude compensation.

In some embodiments, for the first compensation amount, the management platform 110 may determine the two corresponding second compensation amounts by multiplying the first compensation amount by the two sub-amplitudes in the pulse amplitude. For example, for the X-axis compensation amount

$$\frac{{P}_{{total}_{x}}}{N} = 10 μm$$

of the first compensation amount at the compensation moment tᵢ, where the two sub-amplitudes are respectively A₁=0.6 and A₂=0.4, then the two second compensation amounts corresponding to the first compensation amount in the X-axis direction are respectively 6 μm and 4 μm, and decomposition manners of the Y-axis compensation amount and the Z-axis compensation amount in the first compensation amount are similar.

The second angle refers to a specific rotation angle value to be executed by the servo motor in the single second compensation instruction (corresponding to the single second compensation instruction). In some embodiments, the first compensation instruction may be decomposed into two second compensation instructions, and the first angle corresponding to the first compensation instruction may be decomposed into two second angles respectively included in the two second compensation instructions.

In some embodiments, for a first angle, the management platform 110 may determine the two corresponding second angles by multiplying the first angle by the two sub-amplitudes in the pulse amplitude.

Similar to the process of generating the first compensation instruction, the management platform 110 may package the calculated second angle, a corresponding target axis identifier, and a timestamp into a data packet to generate the second compensation instruction. More descriptions regarding how to generate the first compensation instruction may be found elsewhere in the present disclosure (e.g., FIG. 2 and the related descriptions thereof).

In 330, at the compensation moment, sending one of the two second compensation instructions to a controller, and after an interval of the vibration period, sending the other of the two second compensation instructions to the controller, so that the controller controls a servo motor to rotate by a corresponding second angle based on each second compensation instruction to drive a worktable to move by a corresponding second compensation amount, and a sum of two second compensation amounts corresponding to the two second compensation instructions is the first compensation amount.

After obtaining the two second compensation instructions corresponding to the first compensation instruction, the management platform 110 sends the two second compensation instructions in two times, instructing the servo motor to rotate the corresponding two second angles in two times to achieve self-cancellation of mechanical vibration. A sending moment of the second compensation instruction refers to a sub-compensation moment. Among the two second compensation instructions corresponding to the first compensation instruction, the sub-compensation moment corresponding to the first sent second compensation instruction is equivalent to a compensation moment corresponding to the first compensation instruction. The sub-compensation moment corresponding to the second sent second compensation instruction is a moment after the interval of the vibration period from the compensation moment corresponding to the first compensation instruction.

It should be noted that, since a vibration amplitude excited by a compensation action decays exponentially over time, an inverse wave generated by the later compensation action can accurately match and cancel out a residual vibration wave after decay only when the later compensation action is slightly smaller than the earlier compensation action. Therefore, when sending the two second compensation instructions corresponding to the first compensation instruction, the management platform 110 strictly follows a principle of “larger first, then smaller” (e.g., sending the second compensation instruction with the larger second compensation amount first).

The manner of sending the second compensation instruction to the controller is similar to the manner of sending the first compensation instruction to the controller. More descriptions may be found elsewhere in the present disclosure (e.g., FIG. 2 and the related descriptions thereof).

More descriptions regarding the controller controlling the servo motor to rotate and controlling the worktable to move may be found elsewhere in the present disclosure (e.g., FIG. 2 and the related descriptions thereof).

In some embodiments, the management platform 110 is further configured to generate an inverted vibration signal of the machine tool based on a medium-frequency component of the recent eddy current data, and adjust the second compensation instructions based on the inverted vibration signal.

More descriptions regarding the recent eddy current data may be found elsewhere in the present disclosure (e.g., FIG. 2 and the related descriptions thereof).

The medium-frequency component refers to a medium-frequency signal in the recent eddy current data, which is caused by mechanical vibration. The medium-frequency component is fully aligned in time with the recent eddy current data, and both correspond to the recent period. A frequency of the medium-frequency component is consistent with that of the recent spindle speed data at each recent moment.

In some embodiments, the management platform 110 may decompose the medium-frequency component from the recent eddy current data using a preset decomposition algorithm.

The preset decomposition algorithm may be a signal decomposition algorithm, such as a Variational Mode Decomposition (VMD) algorithm, or the like.

In some embodiments, the management platform 110 may use the recent eddy current data as an input of the preset decomposition algorithm to obtain the medium-frequency component.

In some embodiments of the present disclosure, obtaining the medium-frequency component through the preset decomposition algorithm can accurately lock a main mechanical vibration source that causes machining marks or error, thereby providing a clean and accurate data basis for subsequent generation of the inverted vibration signal.

The inverted vibration signal refers to a signal generated based on the medium-frequency component, having an opposite phase to the medium-frequency component in the time domain.

In some embodiments, the management platform 110 may perform phase reversal processing (e.g., a phase shift of 180°) on the decomposed medium-frequency component to obtain an inverted vibration signal having the same frequency and an opposite phase as the medium-frequency component.

In some embodiments, the management platform 110 may, according to the sensitivity of the eddy current position sensor corresponding to the medium-frequency component, directly convert the inverted vibration signal into a displacement; align the inverted vibration signal in the time domain with timestamps of the plurality of second compensation instructions; at each aligned sub-compensation moment, add the displacement corresponding to the inverted vibration signal at the sub-compensation moment to the second compensation amount corresponding to the second compensation instruction at the sub-compensation moment to obtain an adjusted second compensation amount; and generate an adjusted second compensation instruction based on the adjusted second compensation amount.

More descriptions regarding the sensitivity may be found elsewhere in the present disclosure (e.g., FIG. 2 and the related descriptions thereof). More descriptions regarding generating the adjusted second compensation instruction may be found in the preceding related descriptions regarding generating the second compensation instruction.

In some embodiments of the present disclosure, an adjustment mechanism based on the medium-frequency component in the recent eddy current data substantially introduces a feedforward active vibration suppression function into the system, which allows the machine tool, when performing a compensation action, to suppress ripple or surface roughness problems caused by structural resonance, thereby significantly improving the dynamic accuracy and surface quality of precision machining.

In some embodiments of the present disclosure, by decomposing the single compensation action into two components that can cancel each other out, and utilizing subsequent instructions to actively cancel mechanical resonance excited by preceeding instructions, the natural decay waiting time of the machine tool is eliminated, and the dynamic response speed and machining efficiency of the machine tool are significantly improved. Targeting inherent damping characteristics of mechanical systems, the present disclosure adopts an instruction decomposition manner of “larger first, then smaller”, which ensures that a vibration cancellation wave generated by the subsequent second compensation instruction precisely matches in amplitude and eliminates the vibration wave caused by the first compensation instruction, thereby achieving highest precision vibration suppression and further improving the machining precision of the machine tool.

FIG. 4 is a schematic diagram illustrating an exemplary process of determining a spindle offset according to some embodiments of the present disclosure.

In some embodiments, as shown in FIG. 4, the management platform 110 is further configured to determine a predicted offset sequence 440 of a spindle based on recent spindle speed data 410 and recent temperature data 420 using an error prediction model 430; where the error prediction model 430 is a machine learning model; determine an actual offset sequence 460 of the spindle based on recent eddy current data 450 of the spindle; and determine a spindle offset 470 based on the predicted offset sequence 440 and the actual offset sequence 460.

More descriptions regarding the recent spindle speed data, the recent temperature data, and the spindle offset may be found elsewhere in the present disclosure (e.g., FIG. 2 and the related descriptions thereof).

The predicted offset sequence 440 refers to predicted spindle offsets at a plurality of recent moments within a recent period. In some embodiments, the predicted offset sequence 440 may be a multi-dimensional vector sequence that includes a predicted X-axis runout, a predicted Y-axis runout, and a predicted Z-axis displacement. For example, the predicted offset sequence may be a sequence of predicted spindle offsets with timestamps arranged chronologically.

More descriptions regarding the recent period and the recent moments may be found elsewhere in the present disclosure (e.g., FIG. 2 and the related descriptions thereof).

The error prediction model 430 refers to a model configured to obtain the predicted offset sequence. In some embodiments, the error prediction model 430 may be a machine learning model, such as Long Short-Term Memory (LSTM) networks, Recurrent Neural Network (RNN) networks, or the like.

In some embodiments, an input of the error prediction model 430 may include the recent spindle speed data 410 and the recent temperature data 420; and an output of the error prediction model 430 may include the predicted offset sequence 440.

In some embodiments, the error prediction model 430 may be trained using a plurality of training samples with training labels. The training samples may include sample speed data and sample temperature data. The training labels may be a sample offset sequence corresponding to the training samples.

The training samples may be obtained from historical data. For example, the management platform 110 may read historical speed data and historical temperature data at a plurality of historical moments within a historical period from historical operation logs to construct the sample speed data and the sample temperature data; correspondingly, theoretical spindle offsets at the plurality of historical moments within the historical period may be manually labeled to construct the sample offset sequence.

In some embodiments, the management platform 110 may input the plurality of training samples with the training labels into an initial error prediction model, construct a loss function based on the training labels and output results of the initial error prediction model, and iteratively update parameters of the initial error prediction model based on the loss function using approaches such as gradient descent, or the like. When a preset condition is satisfied, the model training is completed, thereby obtaining a trained error prediction model.

In some embodiments, the preset condition may be convergence of the loss function, a count of iterations reaching a threshold, or the like.

In some embodiments, the input of the error prediction model 430 further includes a recent compensation sequence 480.

The recent compensation sequence 480 refers to a sequence composed of a plurality of compensation action intensities within the recent period. In some embodiments, the compensation action intensity may be represented by a pulse change rate. In some embodiments, the management platform 110 may determine a pulse increment within a single compensation operation based on an offset compensation amount and a machine tool resolution, where the pulse change rate is equal to the pulse increment within the single compensation operation divided by an instruction sending period. When the offset compensation amount is a first compensation amount, the instruction sending period refers to a time interval of two compensation moments corresponding to two adjacent first compensation instructions. When the offset compensation amount is a second compensation amount, the instruction sending period refers to a time interval of two sub-compensation moments corresponding to two adjacent second compensation instructions.

In some embodiments, the training samples may further include a sample compensation sequence. The sample compensation sequence may be obtained based on the historical data. For example, the management platform 110 may read the compensation action intensities at the plurality of historical moments within the historical period from the historical operation logs to construct the sample compensation sequence.

In some embodiments of the present disclosure, by introducing a historical compensation intensity sequence into the error prediction model, physical-level decoupling is achieved, and “secondary thermal deformation” interference is eliminated.

The recent eddy current data 450 is eddy current sensing data corresponding to a current moment, and may be obtained based on an eddy current position sensor. More descriptions regarding eddy current sensing data and the eddy current position sensor may be found elsewhere in the present disclosure (e.g., FIG. 2 and the related descriptions thereof).

The actual offset sequence 460 refers to actual spindle offsets at the plurality of recent moments within the recent period. Similar to the predicted offset sequence, the actual offset sequence may be a multi-dimensional vector sequence that includes an X-axis actual runout, a Y-axis actual runout, and a Z-axis actual displacement. For example, the actual offset sequence may be a sequence of actual spindle offsets with timestamps arranged chronologically, and configured to record actual motion trajectories of the spindle within the recent period.

In some embodiments, the management platform 110 may directly convert the recent eddy current data into a displacement amount based on a sensitivity of the eddy current position sensor, thereby obtaining the actual offset sequence.

In some embodiments, the management platform 110 is further configured to determine an intrinsic mode function (IMF) 451 based on the recent eddy current data 450 using a preset decomposition algorithm; determine environmental noise 453 based on waveform characteristics 452 of the IMF 451; remove the environmental noise 453 from the recent eddy current data 450 to obtain recent eddy current data after noise reduction 454; and determine the actual offset sequence 460 based on the recent eddy current data after noise reduction 454.

More descriptions regarding the preset decomposition algorithm may be found elsewhere in the present disclosure (e.g., FIG. 3 and the related descriptions thereof).

The IMF refers to a plurality of single-component signals obtained by decomposing complex non-stationary eddy current sensing data using the preset decomposition algorithm.

In some embodiments, the waveform characteristics may include a center frequency, an average amplitude, an instantaneous frequency, a zero-crossing rate, a bandwidth, and a kurtosis.

In some embodiments, the management platform 110 may obtain the waveform characteristics of the IMF using calculation modes such as a Hilbert Transform, or the like.

The environmental noise refers to signal components caused by non-thermal deformation in the eddy current sensing data. In some embodiments, the environmental noise includes high-frequency interference noise caused by chip splashing or high-pressure impact of coolant during a cutting process, and medium-frequency mechanical noise caused by mechanical vibration, which is caused by rotation of the spindle of the machine tool or cutting force.

In some embodiments, the management platform 110 may determine whether the IMF corresponding to the waveform characteristics is the environmental noise based on the waveform characteristics by querying a preset rule table. The preset rule table stores different signal types corresponding to different waveform characteristics. The signal types may be classified into environmental noise and non-environmental noise. The preset rule table may be pre-constructed manually.

The recent eddy current data after noise reduction refers to recent eddy current data from which the environmental noise has been removed.

In some embodiments, the management platform 110 may directly convert the recent eddy current data after noise reduction into a displacement amount based on the sensitivity of the eddy current position sensor, thereby determining the actual offset sequence.

In some embodiments of the present disclosure, by selectively removing IMF components that match specific noise characteristics, high-frequency mechanical vibration information of the spindle (i.e., runout waveforms synchronized with spindle speed) is perfectly preserved, allowing the determined “actual offset sequence” to have extremely high real-time performance and fidelity in the time domain. Furthermore, by using statistical indicators such as the waveform characteristics, or the like, the environmental noise is accurately identified and removed, ensuring that subsequently extracted “peak/valley values” are true mechanical geometric features rather than noise interference, thereby preventing the machine tool from performing incorrect compensation actions due to misjudgment.

In some embodiments, the management platform 110 may determine the spindle offset based on the predicted offset sequence and the actual offset sequence using prediction correction algorithms such as a Kalman filter algorithm, or the like.

The eddy current position sensor may experience zero-point drift due to oil contamination or temperature fluctuations during long-term use. In some embodiments of the present disclosure, predicted values from the neural network model may serve as a benchmark reference to correct the long-term drift of the sensor, while real-time sensor data may instantly capture dynamic errors not predicted by the model, the combination of which achieves a perfect integration of “long-term thermal stability” and “transient response sensitivity”, ensuring that the machine tool consistently maintains micron-level compensation accuracy during long-term continuous machining.

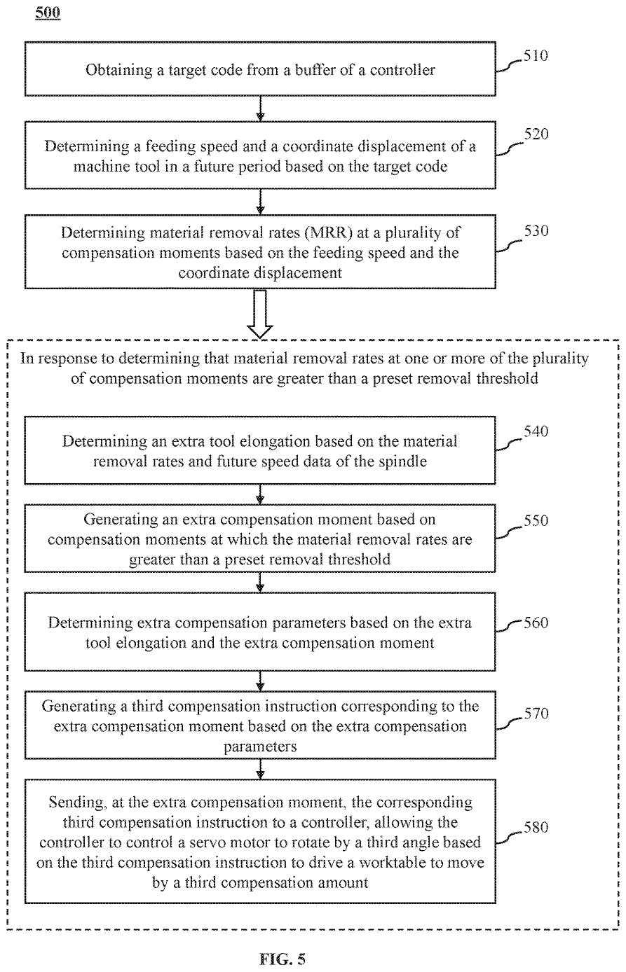

FIG. 5 is a flowchart illustrating an exemplary process of generating and sending a third compensation instruction according to some embodiments of the present disclosure. A process 500 includes operations 510 to 580. In some embodiments, the process 500 may be executed by the management platform 110 of the system 100.

In 510, obtaining a target code from a buffer of a controller.

The buffer refers to a high-speed storage region reserved inside the controller, and is configured to temporarily store instruction data that has been read but not yet executed.

The target code refers to program code (e.g., Geometric Code (G-code)) stored in the buffer and to be executed, and is configured to command the machine tool for machining.

In some embodiments, the management platform 110 may poll buffer registers of the controller in real time through an application programming interface (API) or a fieldbus (e.g., Fanuc FOCAS, Siemens Snap7) to obtain the target code.

In 520, determining a feeding speed and a coordinate displacement of a machine tool in a future period based on the target code.

More descriptions regarding the future period may be found elsewhere in the present disclosure (e.g., FIG. 2 and the related descriptions thereof).

The feeding speed refers to a moving rate of the tool relative to a surface of a workpiece.

The coordinate displacement refers to a displacement amount of a worktable along X, Y, and Z axes.

In some embodiments, the management platform 110 may directly read the feeding speed and the coordinate displacement of the machine tool within the future period from the target code.

In 530, determining material removal rates (MRR) at a plurality of compensation moments based on the feeding speed and the coordinate displacement.

The MRR refers to a volume of material removed from the workpiece by the tool per unit time.

In some embodiments, the management platform 110 may determine the MRR based on the feeding speed and the coordinate displacement using the following formula (5):

MRR=aₚ×aₓ×a_{ey}×V_{f} (5),

where MRR represents the material removal rate, V_{f} represents the feeding speed; aₚ represents a cutting depth, which may be represented by a coordinate displacement of the machine tool in a Z-axis direction; and aₑₓ and a_{ey} represent cutting widths of the X-axis and the Y-axis, respectively, which may be represented by coordinate displacements of the machine tool in an X-axis direction and a Y-axis direction, respectively.

In some embodiments, it is known that there are two cases: the MRR being less than or equal to a preset removal threshold, and the MRR being greater than the preset removal threshold. In response to determining that the MRR is less than or equal to the preset removal threshold, the management platform 110 determines that a normal cutting condition is currently present, and no extra thermal error correction is required, so that the third compensation instruction is not generated. In response to determining that the MRR at one or more of the plurality of compensation moments is greater than the preset removal threshold, the system 100 may execute the following operations 540 to 580.

In some embodiments, the preset removal threshold may be set based on manual experience or historical experience.

In 540, determining an extra tool elongation based on the material removal rates and future speed data of the spindle.

The future speed data refers to spindle speed data at the plurality of compensation moments within the future period. In some embodiments, the management platform 110 may directly obtain the future speed data from the target code.

The extra tool elongation refers to an extra thermal elongation of the tool caused by a rate of increase in the MRR exceeding a rate-of-increase threshold (where a step temperature rise occurs), which is primarily an elongation along the Z-axis. The rate-of-increase threshold is manually preset.

In some embodiments, the management platform 110 may obtain the extra tool elongation based on the MRR and the future speed data by querying a first vector database. For example, the management platform 110 may construct a first feature vector based on the MRR and future spindle speeds corresponding to compensation moments within the future period; retrieve the first feature vector in the first vector database; determine a similarity (e.g., a cosine similarity) between the first feature vector and a plurality of first reference vectors stored in the database; select one or more first reference vectors with a highest similarity to the first feature vector, obtain a corresponding first vector label thereof; and determine the first vector label as the extra tool elongation.

In some embodiments, the management platform 110 may construct the first vector database based on a large amount of historical data. For example, the management platform 110 may construct a plurality of first reference vectors based on historical material removal rates and historical speed data at a plurality of historical moments in historical data. Each first reference vector has a corresponding first vector label. The first vector label may be a historical actual measured extra tool elongation (a difference between an actual tool elongation and a standard tool elongation under a standard MRR) when a step temperature rise occurs. The standard MRR may be set based on manual experience or historical experience.

In some embodiments, the management platform 110 is further configured to determine cutting contact conditions at the plurality of compensation moments based on the target code; and determine the extra tool elongation based on the MRR, the future spindle speeds, and the cutting contact conditions.

The cutting contact conditions refer to a comprehensive parameter set describing a micro-contact state and a thermophysical state of the tool and the workpiece during a cutting process. In some embodiments, the cutting contact conditions specifically include geometric parameters and physical parameters.

The geometric parameters include a tool contact angle and a cutting contact area. The tool contact angle refers to a central angle at which a cutting edge of the tool maintains contact with a workpiece material on a radial plane.

More descriptions regarding the radial plane may be found elsewhere in the present disclosure (e.g., FIG. 2 and the related descriptions thereof).

The physical parameters include a heat distribution coefficient and a cutting edge temperature field distribution. The heat distribution coefficient refers to a ratio of heat flowing into the tool, the workpiece, and removed by chips, respectively, among total heat generated in a cutting zone. The cutting edge temperature field distribution is configured to describe a temperature gradient distribution in a cutting edge contact area of the tool.

In some embodiments, the management platform 110 may call machining simulation software (e.g., VERICUT, NCSIMUL, or ModuleWorks Simulation, or the like) to perform virtual machining simulation on the target code to obtain the cutting contact conditions.

In some embodiments, the management platform 110 may construct a second feature vector based on the MRR, the future spindle speeds, and the cutting contact conditions at the compensation moments within the future period; retrieve the second feature vector in a second vector database, and determine a similarity (e.g., a cosine similarity) between the second feature vector and a plurality of second reference vectors stored in the database; select one or more second reference vectors with a highest similarity to the second feature vector, obtain a corresponding second vector label thereof, and determine the second vector label as the extra tool elongation.

The construction manner of the second vector database is the same as the construction manner of the first vector database, which is not described in detail here.

In some embodiments of the present disclosure, by introducing the cutting contact conditions and simulation technology, the deep analysis of a thermal error mechanism is achieved. In actual machining, a large depth of cut and small cutting width, and a large cutting width and small depth of cut may generate the same MRR. However, due to significantly different tool contact angles and heat dissipation conditions, a large difference in heat flowing into the tool is caused. By introducing the “cutting contact conditions”, the management platform 110 can identify this difference, avoiding prediction deviations caused by relying solely on the MRR, thereby achieving more accurate and physically realistic prediction and compensation of the extra tool elongation.

In 550, generating an extra compensation moment based on compensation moments at which the material removal rates are greater than a preset removal threshold.

The extra compensation moment refers to a specific time point or time window that is expected to generate significant thermal deformation due to high-load cutting, and thus requires performing a superimposed compensation action.

In some embodiments, the management platform 110 may use a moment prior to a compensation moment, where the MRR is greater than the preset removal threshold by a preset duration, as the extra compensation moment. The preset duration may be manually preset based on experience, such as 0.5 s.

In 560, determining extra compensation parameters based on the extra tool elongation and the extra compensation moment.

In some embodiments, the extra compensation parameters include the extra compensation moment and a third compensation amount corresponding to the extra compensation moment.

The extra compensation parameters are supplementary parameters independent of compensation parameters. More descriptions regarding the compensation parameters may be found elsewhere in the present disclosure (e.g., FIG. 2 and the related descriptions thereof).

The third compensation amount refers to a compensation amount for the extra tool elongation. In some embodiments, the management platform 110 may determine the third compensation amount based on the extra tool elongation by querying a second preset table. The second preset table may be pre-constructed manually. The extra tool elongation may be positively correlated with the third compensation amount.

In 570, generating a third compensation instruction corresponding to the extra compensation moment based on the extra compensation parameters.

The third compensation instruction refers to a control command configured to drive underlying hardware to perform an offset extra compensation action.

A third angle refers to an angle value by which a servo motor needs to rotate to achieve the third compensation amount. In some embodiments, the management platform 110 may determine the third angle based on the third compensation amount by querying a first preset table. The first preset table may be set manually based on machine tool specifications combined with experience. More descriptions regarding the first preset table may be found elsewhere in the present disclosure (e.g., FIG. 2 and the related descriptions thereof).

In some embodiments, the management platform 110 may traverse each determined extra compensation moment; convert the third compensation amount corresponding to the compensation moment into a corresponding third angle; package the determined third angle and a timestamp (the extra compensation moment) into a data packet to generate the third compensation instruction; and send all the generated third compensation instructions to a controller in an order of the extra compensation moments.

In 580, sending, at the extra compensation moment, the corresponding third compensation instruction to a controller, allowing the controller to control a servo motor to rotate by a third angle based on the third compensation instruction to drive a worktable to move by a third compensation amount.

The manner of sending the third compensation instruction to the controller is similar to the manner of sending the first compensation instruction to the controller. More descriptions regarding how to send the first compensation instruction to the controller may be found elsewhere in the present disclosure (e.g., FIG. 2 and the related descriptions thereof).

More descriptions regarding the controller controlling the servo motor to rotate and controlling the worktable to move may be found elsewhere in the present disclosure (e.g., FIG. 2 and the related descriptions thereof).

In some embodiments of the present disclosure, by utilizing the buffer forward mechanism of the controller, it is possible to predict the high MRR condition before the cutting action occurs and generate additional third compensation instructions, effectively eliminating the lag of thermal deformation compensation and ensuring the dynamic trajectory accuracy under re-cutting. Meanwhile, the trigger strategy based on the preset removal threshold realizes “on-demand compensation”, avoiding redundant calculations under light loads, and achieving the optimization of computing resources of the numerical control system while ensuring the processing accuracy under high loads.

Basic concepts have been described above. Obviously, for a person skilled in the art, the above detailed disclosure is merely by way of example, and does not constitute a limitation on the present disclosure. Although not expressly stated herein, a person skilled in the art may make various modifications, improvements, and revisions to the present disclosure. Such modifications, improvements, and revisions are contemplated in the present disclosure, and thus, such modifications, improvements, and revisions still fall within the spirit and the scope of the exemplary embodiments of the present disclosure.

The embodiments described in the present disclosure are merely used to illustrate principles of the embodiments of the present disclosure. Other variations may also fall within a scope of the present disclosure. Therefore, by way of example and not limitation, alternative configurations of the embodiments of the present disclosure may be regarded as consistent with teachings of the present disclosure. Accordingly, the embodiments of the present disclosure are not limited to the embodiments expressly introduced and described in the present disclosure.

What is claimed is:

1. A system for error compensation of an eddy current position sensor based on Internet of Things (IoT), comprising a management platform and a perception and control platform; wherein the management platform is configured to:
determine a spindle offset based on recent spindle speed data of a spindle, recent eddy current data, and recent temperature data at a preset position;
determine a tool elongation based on current spindle speed data of the spindle and tool machining parameters;
determine compensation parameters based on the spindle offset and the tool elongation, wherein the compensation parameters include a plurality of compensation moments and a plurality of first compensation amounts corresponding to the plurality of compensation moments;
generate a plurality of first compensation instructions corresponding to the plurality of compensation moments based on the compensation parameters, wherein each of the plurality of first compensation instructions includes a first angle;
send, at each of the plurality of compensation moments, a corresponding one of the plurality of first compensation instructions to a controller of the perception and control platform;
the controller is configured to control, based on the first compensation instruction, a servo motor to rotate the first angle to drive a worktable to move by a corresponding one of the plurality of first compensation amounts.

2. The system according to claim 1, wherein the management platform is further configured to:
determine a vibration period and a pulse amplitude of a machine tool based on natural frequency characteristics of the machine tool and a damping ratio of the machine tool;
for each of the plurality of first compensation amounts corresponding to each of the plurality of compensation moments in the compensation parameters:
generate two second compensation instructions based on the pulse amplitude and the first compensation amount, wherein each of the two second compensation instructions includes a corresponding second angle;
send, at the compensation moment, one of the two second compensation instructions to the controller, and send, after an interval of the vibration period, the other of the two second compensation instructions to the controller;
the controller is further configured to control, based on each of the two second compensation instructions, the servo motor to rotate the corresponding second angle to drive the worktable to move by a corresponding second compensation amount, wherein a sum of two second compensation amounts corresponding to the two second compensation instructions is the first compensation amount.

3. The system according to claim 2, wherein the management platform is further configured to:
generate an inverted vibration signal of the machine tool based on a medium-frequency component of the recent eddy current data; and
adjust the two second compensation instructions based on the inverted vibration signal.

4. The system according to claim 3, wherein the management platform is further configured to:
decompose the medium-frequency component from the recent eddy current data using a preset decomposition algorithm.

5. The system according to claim 1, wherein the management platform is further configured to:
determine a predicted offset sequence of the spindle based on the recent spindle speed data and the recent temperature data using an error prediction model, wherein the error prediction model is a machine learning model;
determine an actual offset sequence of the spindle based on the recent eddy current data; and
determine the spindle offset based on the predicted offset sequence and the actual offset sequence.

6. The system according to claim 5, wherein an input of the error prediction model includes a recent compensation sequence.

7. The system according to claim 5, wherein the management platform is further configured to:
determine an intrinsic mode function based on the recent eddy current data using a preset decomposition algorithm;
determine environmental noise based on waveform characteristics of the intrinsic mode function;
remove the environmental noise from the recent eddy current data to obtain recent eddy current data after noise reduction; and
determine the actual offset sequence based on the recent eddy current data after noise reduction.

8. The system according to claim 1, wherein the management platform is further configured to:
obtain a target code from a buffer of the controller;
determine a feeding speed and a coordinate displacement of the machine tool in a future period based on the target code;
determine material removal rates at the plurality of compensation moments based on the feeding speed and the coordinate displacement;
in response to determining that material removal rates at one or more of the plurality of compensation moments are greater than a preset removal threshold:
determine an extra tool elongation based on the material removal rates and future speed data of the spindle;
generate an extra compensation moment based on the compensation moments at which the material removal rates are greater than the preset removal threshold;
determine extra compensation parameters based on the extra tool elongation and the extra compensation moment, wherein the extra compensation parameters include the extra compensation moment and a third compensation amount corresponding to the extra compensation moment;
generate a third compensation instruction corresponding to the extra compensation moment based on the extra compensation parameters, wherein the third compensation instruction includes a third angle;
send, at the extra compensation moment, the third compensation instruction to the controller;
the controller is further configured to control, based on the third compensation instruction, the servo motor to rotate by the third angle to drive the worktable to move by the third compensation amount.

9. The system according to claim 8, wherein the management platform is further configured to:
determine cutting contact conditions at the plurality of compensation moments based on the target code; and
determine the extra tool elongation based on the material removal rates, the future speed data, and the cutting contact conditions.

10. A method for error compensation of an eddy current position sensor based on Internet of Things (IoT), comprising:
determining a spindle offset based on recent spindle speed data of a spindle, recent eddy current data, and recent temperature data at a preset position;
determining a tool elongation based on current spindle speed data of the spindle and tool machining parameters;
determining compensation parameters based on the spindle offset and the tool elongation, wherein the compensation parameters include a plurality of compensation moments and a plurality of first compensation amounts corresponding to the plurality of compensation moments;
generating a plurality of first compensation instructions corresponding to the plurality of compensation moments based on the compensation parameters, wherein each of the plurality of first compensation instructions includes a first angle; and
sending, at each of the plurality of compensation moments, a corresponding one of the plurality of first compensation instructions to a controller of a perception and control platform, so that the controller controls, based on the first compensation instruction, a servo motor to rotate the first angle to drive a worktable to move by the first compensation amount.

11. The method according to claim 10, further comprising:
determining a vibration period and a pulse amplitude of a machine tool based on natural frequency characteristics of the machine tool and a damping ratio of the machine tool;
for each of the plurality of first compensation amounts corresponding to each of the plurality of compensation moments in the compensation parameters:
generating two second compensation instructions based on the pulse amplitude and the first compensation amount, each of the two second compensation instructions including a corresponding second angle;
at the compensation moment, sending one of the two second compensation instructions to the controller, and after an interval of the vibration period, sending the other of the two second compensation instructions to the controller, so that the controller controls the servo motor to rotate by the corresponding second angle based on each second compensation instruction to drive the worktable to move by a corresponding second compensation amount, and a sum of two second compensation amounts corresponding to the two second compensation instructions is the first compensation amount.

12. The method according to claim 11, further comprising:
generating an inverted vibration signal of the machine tool based on the medium-frequency component of the recent eddy current data;
adjusting the two second compensation instructions based on the inverted vibration signal.

13. The method according to claim 11, characterized in that the method further comprises:
decomposing the medium-frequency component from the recent eddy current data using a preset decomposition algorithm.

14. The method according to claim 10, wherein the determining a spindle offset based on recent spindle speed data of a spindle, recent eddy current data, and recent temperature data at a preset position includes:
determining a predicted offset sequence of the spindle based on the recent spindle speed data and the recent temperature data using an error prediction model; wherein the error prediction model is a machine learning model;
determining an actual offset sequence of the spindle based on the recent eddy current data; and
determining the spindle offset based on the predicted offset sequence and the actual offset sequence.

15. The method according to claim 14, wherein an input of the error prediction model includes a recent compensation sequence.

16. The method according to claim 14, wherein the determining an actual offset sequence of the spindle based on the recent eddy current data includes:
determining an intrinsic mode function based on the recent eddy current data using a preset decomposition algorithm;
determining environmental noise based on waveform characteristics of the intrinsic mode function;
removing the environmental noise from the recent eddy current data to obtain recent eddy current data after noise reduction; and
determining the actual offset sequence based on the recent eddy current data after noise reduction.

17. The method according to claim 10, further comprising:
obtaining a target code from a buffer of the controller;
determining a feeding speed and a coordinate displacement of the machine tool in a future period based on the target code;
determining material removal rates at a plurality of compensation moments based on the feeding speed and the coordinate displacement;
in response to determining that material removal rates at one or more of the plurality of compensation moments are greater than a preset removal threshold:
determining an extra tool elongation based on the material removal rates and future speed data of the spindle;
generating an extra compensation moment based on the compensation moments at which the material removal rates are greater than the preset removal threshold;
determining extra compensation parameters based on the extra tool elongation and the extra compensation moment; the extra compensation parameters including the extra compensation moment and a third compensation amount corresponding to the extra compensation moment;
generating a third compensation instruction corresponding to the extra compensation moment based on the extra compensation parameters, the third compensation instruction including a third angle; and
sending, at the extra compensation moment, the third compensation instruction to the controller, so that the controller controls the servo motor to rotate by the third angle based on the third compensation instruction to drive the worktable to move by the third compensation amount.

18. The method according to claim 17, wherein the determining an extra tool elongation based on the material removal rates and future speed data includes:
determining cutting contact conditions at the plurality of compensation moments based on the target code; and
determining the extra tool elongation based on the material removal rates, the future speed data, and the cutting contact conditions.

19. A non-transitory computer-readable storage medium, wherein the storage medium stores computer instructions, and when a computer reads the computer instructions in the storage medium, the computer executes the method for error compensation of the eddy current position sensor based on the Internet of Things (IoT) according to claim 10.
